(19) United States
(12) Patent Application Publication
(10) Pub. No.: US 2005/0079450 A1
(43) Pub. Date: Apr. 14, 2005

(54) Method for manufacturing ceramic green sheet and method for manufacturing electronic part using that ceramic green sheet

(75) Inventors: Masayuki Yoshida, Tokyo (JP); Junichi Sutoh, Tokyo (JP); Shunji Aoki, Tokyo (JP); Genichi Watanabe, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK CORPORATION, Tokyo (JP)

(21) Appl. No.: 10/926,085

(22) Filed: Aug. 26, 2004

(30) Foreign Application Priority Data
Aug. 28, 2003 (JP) 2003-304218

(51) Int. Cl. G03F 7/00

(52) U.S. Cl. 430/322; 430/320; 430/396

(57) ABSTRACT

There is provided a sheet used for manufacturing multilayer electronic parts in which accuracy in shape and formation position and uniformity in thickness of a complex configuration with recesses and projections of an insulating layer or the like are assured. A layer made of a photosensitive material containing a powder having a specific electric characteristic is formed on a light transmissive base member. A mask having a plurality of patterns with different transmittances for ultraviolet light is disposed on the back side of the base member. The photosensitive material is subjected to an exposure process in which it is irradiated with ultraviolet light or the like through the mask. The photosensitive material is subjected to development process after the exposure process.

### BACKGROUND OF THE INVENTION

1. Field of the Invention

The present invention relates to a method for manufacturing an electronic part, especially an electronic part that is formed by laminating ceramic layers, which is exemplified by a so-called multilayer ceramic electronic part. The present invention also relates to a method for manufacturing a so-called ceramic green sheet used in the aforementioned method. Examples of the multiplayer electronic part mentioned here include multilayer ceramic capacitors, multilayer ceramic inductors, LC composite parts including capacitors and inductors formed therein, or EMC related parts etc.

2. Related Background Art

In recent years, with downsizing and rapid popularization of electronic apparatuses represented by cellular phones, an increase in mounting density of the electronic parts used for those apparatuses and improvement in their performance are required. Especially, demands for downsizing, decrease in thickness, increase in the number of layers and uniformization of each layer are placed on multilayer electronic parts that are used as passive elements in order to meet the above requirements. In addition, development of the manufacturing method that can meet those requirements is also demanded.

So-called metal-ceramic combined sintering, disclosed in, for example, Japanese Patent Application Laid-Open No. 2001-110662 and Japanese Patent Application Laid-Open No. 2001-85264, is a conventional manufacturing method used for manufacturing the aforementioned multilayer electronic parts exemplified by multilayer ceramic capacitors having electrodes formed in the interior thereof, which can meet the aforementioned requirements. Here, this metal-ceramic combined sintering technology will be described briefly. In this technology, a plurality of electrodes are formed on a so-called ceramic green sheet at the same time using an electrically conductive paste composed of a metal powder and an organic binder material.

Subsequently, a plurality of simple ceramic green sheets and ceramic green sheets on which electrodes have been formed etc. are stacked to form a ceramic multilayer member. The electrodes will constitute the internal electrodes of a multilayer electronic part when it is finished. In addition, the ceramic multilayer member is pressed in its thickness direction so that the green sheets will be brought into close contact with each other. The multilayer member brought into close contact is cut into a certain size and separated so as to be subjected to sintering. On the outer surface of the sintered member thus obtained, external electrodes are formed fitly. Thus, a multilayer electronic part is obtained.

In recent years, further downsizing and thickness reduction of the aforementioned multilayer electronic parts have been required, and it is necessary to reduce the thickness of dielectric layers made of a ceramic or the like sandwiched between internal electrodes. Therefore, it is required to perform the above-described process while further reducing the thickness of ceramic green sheets that constitute the ceramic multilayer member. In view of these requirements, the thickness of the thinnest ceramic green sheet presently used is about 2 to 3 μm. In addition, the thickness of electrodes printed on the ceramic green sheets is about 1.5 to 2.0 μm.

The thickness of the ceramic green sheets and the electrodes formed on the surface thereof, the width and pattern shape of the electrodes, are substantially determined at the time when they are formed, and it is practically impossible to add a process of shaping them after they are formed. Conventionally, the electrodes or the like are formed by screen printing. In the screen printing, variations in the thickness in the formed area is ±10 to 20%, and the limit value of the pattern width that can be formed is considered to be about 50 μm. As disclosed in Japanese Patent Application Laid-Open No. 2002-184648, on the surface of a sheet produced by the screen printing, there is unevenness like an impression of a mesh. In view of this, new production method is required to be devised in order to produce sheets having improved uniformity in thickness and improved surface evenness.

As one solution, there has been proposed a technology in which a sheet or layer having a desired thickness is formed by a ceramic slurry having photosensitivity or an electrode paste having photosensitivity, so that they are subjected to exposure and development processing to produce electrodes or the like with high accuracy in the width and shape etc. With that method it is possible to make the pattern width thinner and the positional accuracy of pattern formation can also be enhanced as compared to the printing process. However, in the case that the layer to be exposed is formed by a printing process, there will be the aforementioned unevenness of the layer surface, and the unevenness will remain unchanged even when ordinary exposure and development processing has been applied.

It may be possible to reduce the unevenness by applying mechanical processing such as pressing to the sheet or the layer after the sheet or the layer is formed. However, it is not desirable because the process will become lengthy. A method using a coater or spin coating process is another method for forming a sheet or a layer having no or reduced unevenness. However, on the surface of the layer obtained by the aforementioned coating process, there remains traces of a blade or the like and the variations in the thickness is ±3 to 5%, which will still remain after the exposure and development processing. Therefore, in order to manufacture electronic parts having improved characteristics, improvement in the surface evenness or reduction of the variations in the thickness is required.

In the case that metal paste is applied on a base member by screen printing or using a coater to form an electrode layer, sag of the edge portion of the electrode or deterioration in straightness of the edge portion can occur depending on conditions such as viscosity of the metal paste etc. In addition, a run-over or faded portion can be generated upon application of slurry, which can cause short-circuit or conduction failure when assembled into an electronic part. Furthermore, upon reducing the coating thickness, there is the lower limit of the thickness of the coating that can be formed depending on various conditions such as viscosity. Furthermore, it is difficult to reduce variations in the dimension in the thickness direction down to less than a few percent. This is also the case when a ceramic green sheet is produced using a ceramic slurry.

In the case of a ceramic green sheet that is used for forming an electronic part in the form of an inductor, a penetrating electrode or the like may be formed in some cases. In that case, it is desirable that the length of the penetrating electrode (or the thickness of the electrode) be controlled precisely in order to make electric characteristics of the inductor definite. However, at present, the thickness of the electrode is determined in accordance with the thickness of the ceramic sheet and it is practically difficult to control the thickness of the electrode independently from the thickness of the ceramic green sheet, as will be seen from Japanese Patent Application Laid-Open No. 2003-48303.

Furthermore, in manufacturing inductors or the like, electrodes or other parts are required to be patterned in a complex shape in a plane. It is considered that screen printing can cope with this complexity with a measure of accuracy, but it is difficult to further improve the characteristics of the products as electronic parts. In addition, it is difficult to attain desired cross sectional shape of the electrode or other parts.

Still further, in manufacturing inductors, it is considered preferable to use a ceramic green sheet having pattern electrodes and penetrating electrodes formed in a single sheet from the view point of lamination accuracy, downsizing of the parts or other factors. In that case, it is considered preferable in reducing the number of processes and improving characteristics of the inductors to form the pattern electrodes and the penetrating electrodes by forming partial recessed portions on a layer made of an insulating material and filling the multiple recessed portions with electrode paste, if possible. However, it is impossible for conventional technologies to form such recesses with high accuracy.

### SUMMARY OF THE INVENTION

The present invention have been made in view of the above-described background. An object of the present invention is to provide a method for manufacturing a ceramic green sheet or an electrode layer having desired projected and recessed portions while reducing variations in the surface evenness or thickness. Another object of the present invention is to reduce variations in electric characteristics of multilayer electronic parts by means of that method and to provide electronic parts having improved electric characteristics.

In order to solve the aforementioned problem, according to the present invention there is provided a method for manufacturing a ceramic green sheet utilizing an exposure process and an development process comprising a step of attaching a photosensitive material containing a powder having a specific electric characteristic to a front side surface of a member having a portion that can transmit light used in the exposure process, the photosensitive material being sensitive to the light, and the front side surface being a surface on which a sheet is to be formed, a step of making light quantity of the light different for each of predetermined areas and then irradiating the photosensitive material with that light from the back side of the aforementioned member to perform the exposure process on the photosensitive material, and performing the development process on the photosensitive material after the exposure process.

In the above described manufacturing method, it is preferable that the light quantity of the light be made different for each of the predetermined areas by passing through a mask in which transmittances of its portions corresponding to the predetermined areas are different from each other. In the above-described manufacturing method, it is preferable that the light quantity be differentiated into at least a light quantity obtained by fully blocking the light, a light quantity obtained by fully transmitting the light and a light quantity obtained by partly transmitting the light by a predetermined ratio. In the above-described manufacturing method, it is preferable that the exposure process be terminated when the thickness of the portion of the photosensitive material that is exposed with the light quantity obtained by partly transmitting the light by a predetermined ratio reaches a predetermined thickness.

Furthermore, it is preferable that the above-described method further comprise a step of filling a recessed portion on the ceramic green sheet that is formed by the development process with an electrically conductive material. It is preferable that the above-described manufacturing method further comprise a step of forming a light blocking portion composed of a material that does not transmit the light on a predetermined area of the front side surface of the aforementioned member, prior to the step of attaching the photosensitive material to the front side surface of the aforementioned member. In the above-described manufacturing method, it is preferable that a releasing processing be applied to the aforementioned member to facilitate release of the ceramic green sheet from the surface of the aforementioned member.

In order to solve the aforementioned problem, a sheet manufacturing method according to the present invention is characterized by a step of attaching a photosensitive material containing a powder having a specific electric characteristic to a front side surface of a member having a portion that can transmit light used in the exposure process, the photosensitive material being sensitive to the light, and the front side surface being a surface on which a sheet is to be formed, a step of irradiating the photosensitive material with the light from the back side of the aforementioned member to perform the exposure process on the photosensitive material, light quantity of the light being made different for each of predetermined areas, and a step of performing the development process on the photosensitive material after the exposure process.

In the above-described manufacturing method, it is preferable that the light comprise a light beam and light quantity be made different for each of the predetermined areas by scanning with the light beam. In this case, it is preferable that scanning with the light beam be performed under a condition corresponding to each of the predetermined areas.

In order to solve the aforementioned problem, according to the present invention, there is provided a method for manufacturing a multilayer electronic part comprising a step of stacking a plurality of ceramic green sheets including a ceramic green sheet produced by a method for manufacturing a ceramic green sheet according to any one of the aforementioned methods of manufacturing a ceramic green sheet and a step of applying a pressure to the stacked ceramic green sheets in their thickness direction to form a laminated member.

According to the present invention, a layer formed by a conventional process of applying a photosensitive material for example using a coater or screen printing is processed through exposure and development, so that variations in its position, shape and thickness can be reduced and formation of complex configuration having projections and recesses can be made possible. As a result, it is possible to produce a sheet used for forming multilayer electronic parts having improved quality as compared to conventional sheets only by adding the process according to the present invention to a conventional mass production process.

Furthermore, according to the present invention, it is possible to control the pattern shape, through hole formation and the layer thickness simultaneously. Consequently, in forming a layer including a pattern or a through hole etc., it is possible to shape or process the layer with excellent accuracy in its shape, thickness or other factors. Thus, it is possible to manufacture a preferable sheet to be used for manufacturing multilayer electronic parts having a shape closer to an ideal shape than in conventional methods. More specifically, it is possible to produce a sheet having a pattern width of about 30 μm with variations in thickness of ±2-3% or less.

### BRIEF DESCRIPTION OF THE DRAWINGS

FIG. 1 is schematically shows a ceramic green sheet manufacturing process according to a first embodiment of the present invention.

FIG. 2 is schematically shows a ceramic green sheet manufacturing process according to a second embodiment of the present invention.

FIG. 3 schematically shows a process of manufacturing multilayer ceramic inductors using a ceramic green sheet produced by a method according to the present invention.

FIG. 4 schematically shows a process of manufacturing multilayer ceramic electronic parts having a more complex circuit structure using a ceramic green sheet produced by a method according to the present invention.

FIG. 5 schematically shows a ceramic green sheet manufacturing process according to another embodiment of the present invention, in which a light blocking layer is formed in advance.

FIG. 6 schematically shows a ceramic green sheet manufacturing process according to still other embodiment of the present invention, in which a light blocking layer is formed in advance.

### DESCRIPTION OF THE PREFERRED EMBODIMENTS

An embodiment of a method of producing a sheet (i.e. a so-called ceramic green sheet) used in an electronic part manufacturing process according to the present invention will be described briefly. In this embodiment, a layer made of a photosensitive material containing powder having a desired electric characteristic is firstly formed on the surface of a base member that can transmit light such as ultraviolet light used in an exposure process that will be described later. The photosensitive material that constitutes the layer is sensitive to the aforementioned light such as ultraviolet light. Subsequently, a mask having a certain pattern is disposed on the back side of the base member, and the photosensitive material on the base member is irradiated with light such as ultraviolet light through the mask.

In that process, the exposure amount of the photosensitive material is controlled by adjusting the exposure time, the intensity of the ultraviolet light or other factors. The pattern on the mask is composed of a plurality of patterns having different transmittances. Subsequently, the photosensitive material after the exposure is subjected to a development process and the base member is detached from the photosensitive material. Thus, a ceramic green sheet having a desired shape and layers is obtained.

The embodiments that will be described in the following are directed to the case in which two patterns having different transmittances are present in the mask. However, the present invention it not limited to this, but a mask having more patterns having different transmittances may be used. Although the photosensitive material is designed to be sensitive to light such as ultraviolet light, the light to be used is not limited to ultraviolet light so long as a specific light and a material that is sensitive to that light are used in combination. The aforementioned desired characteristic includes, for example, electro-conductivity, permittivity and resistance. The method of attaching the photosensitive material to the base member may be, for example, coating or printing, though the method is not limited to them. An example of the base member is a PET film that is transparent to light. A member on which releasing processing for facilitating release of the layer made of the photosensitive material formed on the base member is applied may be used as the base member. A member on which a plurality of light transmissive layers are formed may be used as the base member. Although it is preferable that the aforementioned mask having a predetermined pattern be in close contact with the back surface of the base member, it may be disposed spaced apart from the back surface of the base member depending on the exposure condition or other conditions.

In this embodiment, the light used for the exposure process of the photosensitive layer is patterned through the mask disposed on the back side of the base member. However, the position of the mask is not limited to the back side of the base member. A light blocking part that functions in the same manner as the mask may be provided on the base member itself. Alternatively, a light blocking layer having the function same as the mask may be provided on the back side surface of the base member. In other words, the effect of the present invention can also be realized by providing a structure for patterning light in the base member side of the photosensitive material. In addition, the patterned light may be generated by scanning laser beam or the like in a desired pattern or using an area light source such as an LED panel composed of a dot matrix that can be patterned, to perform exposure process for the photosensitive material. More specifically, in the scanning process with a laser beam or the like, it is preferable that scanning time be changed, scanning be performed cumulatively and the number of times of scanning be changed, or the intensity of the laser beam or the like be changed, for each exposure area. In other words, it is preferable that the exposure process be performed with the laser scanning condition that is suitable for each exposed area. The above-described method is to draw a pattern directly on a photosensitive material using an electron beam or the like, which has been studied in recent years as a technology that replaces the exposure process using a mask. With this method, it is possible to form a pattern on a work piece directly based on the design data, and elimination of the mask cost and improvement in the exposure accuracy can be expected. According to this process, it is possible to perform the exposure with different light quantities for each predetermined area by means of the above-mentioned changing processes or a combination of those changing processes.

When patterned light is to be supplied, the exposure process may be performed while shaping an area light source into a predetermined shape by turning on and off multiple light sources that are arranged two-dimensionally. It is also possible to perform the exposure with different light quantities for each predetermined area by performing multiple times of exposure while changing the aforementioned predetermined shape sequentially.

(First Embodiment)

As described in the above general description of the embodiments, in the exposure process, the method of performing exposure with different light quantities for each area by using a simple light source and a mask may includes a method using a simple light source and a mask, a method of drawing a pattern using light having a significant intensity such as laser light, and a method of forming a pattern using an area light source in which a plurality of light sources are arranged. However, the process that is currently used most generally and considered to be most reliable is the process using a mask. Accordingly, a process using a mask will be described as an example.

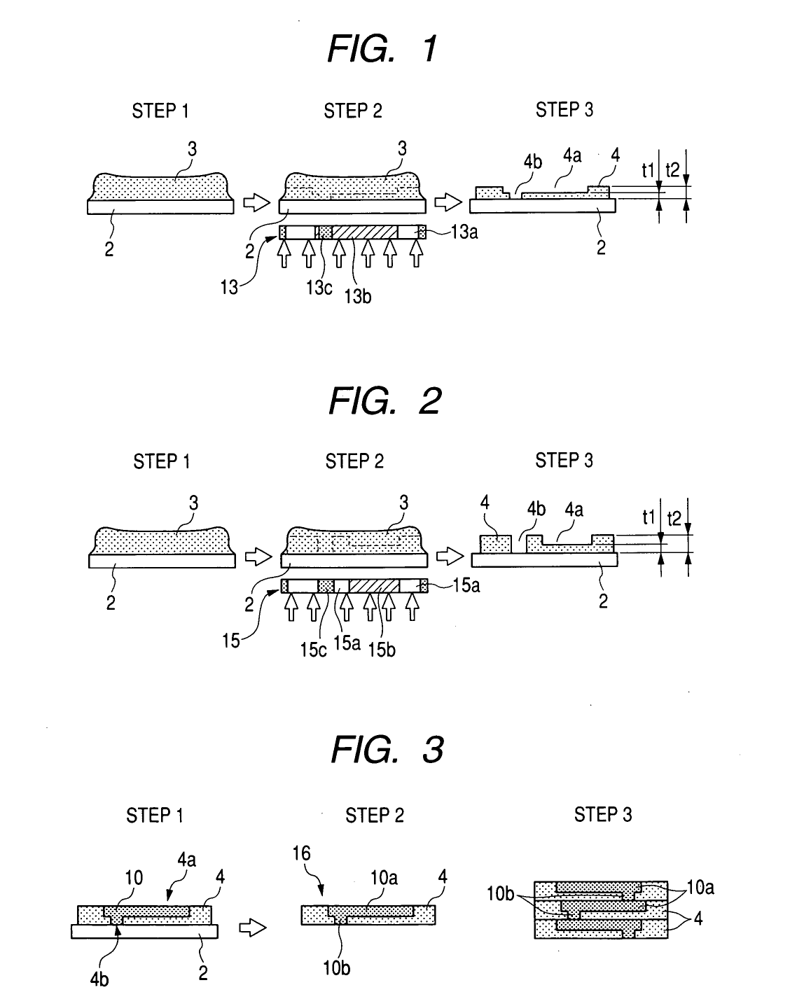

FIG. 1 shows a layer formation process according to the first embodiment of the present invention. FIG. 1 shows a cross sectional structure of layers or a sheet taken in the thickness direction in various stages of the process. In this embodiment, a photosensitive layer 3 containing powder having a desired electric characteristic is formed by coating on a base member 2 made of, for example, a PET film (step 1). Next in step 2, the photosensitive layer 3 is subjected to an exposure process, that is, the photosensitive layer 3 is irradiated with light such as ultraviolet light from the back side of the base member 2.

In connection with the present invention, the applicant of the present patent application discovered the fact that the thickness (or depth) of the cured portion (the exposure amount) in the photosensitive layer 3 measured from the surface of the light transmissive member (in this case, the base member 2) can be controlled by controlling the intensity, radiation time or other factors concerning the ultraviolet light in the exposure. In confirming the controllability of the thickness of the cured portion with the exposure amount, conditions such as the ratio of the ceramic powder mixed in a slurry, dispersibility of the powder, the average particle diameter of the powder, the transmittance of the powder were changed in various ways, and the thickness of the slurry that can be exposed was measured for each condition.

It is well known that when a material in which a ceramic powder or the like and a photosensitive binder are mixed (or kneaded) is exposed with light, diffusion of light generally occurs due to the presence of the ceramic powder or the like, so that the edge of the exposed portion is blurred. The applicant of the present patent application prepared mixtures in which a negative type binder and barium titanate powders having different average particle diameters of 1.0 μm, 0.8 μm, 0.6 μm, 0.4 μm and 0.2 μm respectively are mixed with a volume ratio of 1 to 1 and investigated the relationship between the irradiation time and the thickness of the film remaining after development. As a result, it was confirmed that in the case that the thickness of the remaining film is several microns, more specifically, for any powder, in the case that the thickness is about 10 μm or less, the exposure time and the thickness of the obtained sheet are in a linear relationship and variations in average film thickness values are in the range of ±0.5-2.0%. In addition, in order to keep flatness of the sheet, it can be said that smaller particle diameters are preferable. This depends on the thickness of the sheet, and in the smaller thickness range, the particle diameter is an important factor. Specifically, in the case that the sheet thickness is equal to or smaller than 5 μm, it is preferable to use barium titanate powder having an average particle diameter of equal to or smaller than 0.8 μm, and more preferably, equal to or smaller than 0.2 μm. In other words, a flat sheet can be obtained by using a slurry containing powder with an average particle diameter about one-fifth or less of the thickness of the sheet to be obtained. In addition, a sheet that is reduced in the degree of its surface unevenness (in terms of arithmetic average roughness Ra) can be obtained by using a slurry containing powder with an average particle diameter about one-twentieth or less of the thickness of the sheet to be obtained. Here, the exposure time can be interpreted to the exposure amount taking into account the light intensity, and the result shows that the exposure amount and the thickness of the remaining film are in a linear relationship. Therefore, in the case that a ceramic powder and a photosensitive binder are used, when the thickness of the remaining film is about 5.0 μm as with the thickness of the electrode, it is possible to keep an accurate sheet thickness and evenness of the sheet surface. Although the description of a specific investigation has been made in connection with the case in which barium titanate powders which are inferior in light transmitting characteristics are used, we also investigated so-called glass ceramic powders which are superior in light transmitting characteristics, ferrite powders having light absorbing properties and metal powders. As a result, these powders also showed characteristics similar to the barium titanate powders, though the required exposure amount was different. Therefore, in the case that the thickness of the film remaining after development is to be controlled by adjusting exposure amount while using a slurry in which a metal or ceramic powder and a photosensitive binder are mixed, if the average particle diameter of the powder used is smaller than 1.0 μm, the surface roughness can be made small and a control process that can reduce variations in the average film thickness can be made possible. In addition, with experiments other than mentioned above, it was discovered that the thickness of the film remaining after development can be controlled in the range of about 50 μm or less, if conditions permit.

In this embodiment, based on the above-described discovery, the exposure amount is controlled so that the photosensitive layer 3 is exposed up to a predetermined thickness (or depth). In this process, a mask 13 on which two electrode patterns having different transmittances for ultraviolet light are formed is disposed in close contact with the backside surface of the base member 2, and the photosensitive layer 3 is subjected to an exposure process in which it is irradiated with ultraviolet light through the mask 13.

Pattern 13a of the mask 13 is designed to have a transmittance for ultraviolet light of about 100%, which means total transmission, while pattern 13b is designed to have a transmittance for ultraviolet light of about 50%. Therefore, by performing an exposure process on the photosensitive layer 3 with the exposure amount with which the portion of the photosensitive layer 3 corresponding to the pattern 13a is exposed up to thickness t1, the portion corresponding to the pattern 13b is exposed up to thickness t2 which is about half the thickness t1. The portion of the photosensitive layer 3 corresponding to pattern 13c of the mask 13 that fully blocks ultraviolet light is not exposed.

After the exposure process, a development process is performed, so that only the exposed, cured portions remain, while the other portions are removed. Thus, an insulating (or dielectric) layer 4 with a predetermined shape and a predetermined thickness having a recessed portion 4a and a through hole 4b as shown in step 3 is obtained. The recessed portion 4a corresponds to the pattern 13b and the through hole 4c corresponds to the pattern 13c. As will be described later, the base layer 2 is removed from the obtained sheet composed of the base member 2 and the insulating layer 4 as it is or after an additional layer is formed on top of it. The recessed portion 4a and the through hole 4b of the sheet from which the base member has been removed are filled with an electrode material, and then the sheet is laminated with another sheet that has been made by the same process or a similar process, and formed into a multilayer electronic parts such as inductors after undergoing various processes.

According to this embodiment, it is possible to make the surface of the cured portion even or flat while controlling the thickness of the cured portion accurately. So long as the base member 2 and the insulating layer 4 are transparent to light, this embodiment can be carried out only by adding the exposure process and the development process on top of the conventional coating process.

In this embodiment, the shape or other factors of the electrode is determined by the mask pattern and the controlled exposure amount, and therefore the photosensitive layer may be applied by any process. However in order to reduce the removal amount in the development process, it is preferable that the thickness and other factors of the photosensitive layer 3 formed on the base member 2 be close to that of the insulating layer to be formed. In view of this, various methods including a coating process using a blade may be adopted in forming the photosensitive layer 3. In this embodiment, the insulating layer 4 is formed directly on the base member 2. However, various layers having light transmitting properties may be formed between the insulating layer 4 and the base member 2. Although a process of forming an insulating layer 4 has been described by way of example, an electrode layer having projections and recesses may be formed by replacing the powder contained in the photosensitive material with an electrically conductive powder.

(Second Embodiment)

FIG. 2 is a diagram similar to FIG. 1, which shows a cross sectional structure of layers or a sheet taken along the thickness direction in various stages of the process. The other drawing that will be referred to in the following shall also show a cross sectional structure of the sheet in various stages of a process. This embodiment is directed to a case in which a through hole is formed in an insulating layer 4. Specifically, a photosensitive material 3 is applied on a base member 2 made of a PET film (step 1). Next in step 2, a mask 15 in which a desired electrode pattern 15b and a through hole pattern 15c are separately formed is disposed in close contact with the back side surface of the base member 2, and ultraviolet radiation is applied from the back side thereof.

In this process, the exposure amount is controlled so that the thickness of the cured portion of the photosensitive layer 3 will be t1. The transmittance for ultraviolet light of the pattern 15b is designed to be about half that of the pattern 15a, so that the thickness t2 of the cured portion corresponding to an internal electrode 4a is about half the thickness t1. After the exposure process, a development process is performed, so that only the exposed, cured portions remain, while the other portions are removed. Thus, an insulating (or dielectric) layer 4 with a predetermined shape and a predetermined thickness having a recessed portion 4a and a through hole 4b as shown in step 4 is obtained.

By carrying out this embodiment, it is possible to remove undesired portions such as sag or run-over that are generated when photosensitive material is applied on the surface of a base member or the like simply by keeping those portions unexposed. In addition, since it is not necessary to make the applied photosensitive material layer thin, faded portions will not be generated. In addition, according to the present invention, it is possible to control the thickness of the remaining layer precisely, by controlling the exposure amount. Thus, it is possible to form a layer with a thickness of, for example, smaller than 0.5 μm while reducing variations in thickness down to less than ±2 to 3%. Furthermore, it is possible to make the edge portion of a patterned shape obtained by the exposure and development more square in shape. Thus, it is possible to make variations of electric characteristics of electronic parts produced by laminating the sheets smaller than a desired value.

(Examples of Manufacturing Process of Electronic Parts Using a Sheet According to the Invention)

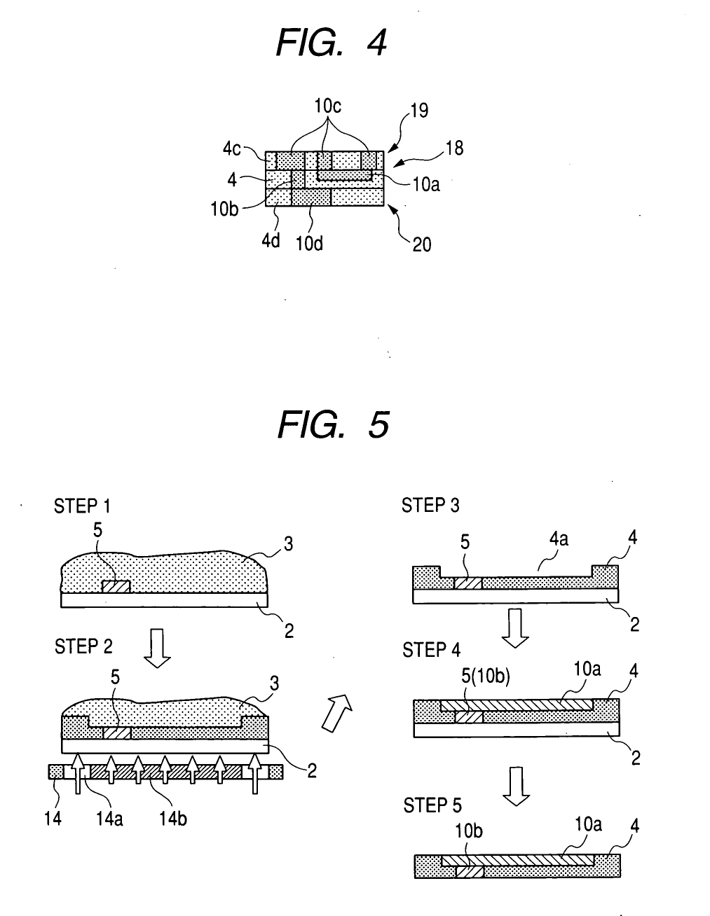

In the following, a process of manufacturing electronic parts using sheets produced by the above-described sheet forming method according to the present invention will be described. FIGS. 3 and 4, which will be referred to in the description of the process, show cross sections of a sheet or laminated sheets taken in the thickness direction as seen from the side. FIG. 3 show various stages of a process of manufacturing multilayer ceramic inductors. FIG. 4 shows various stages of a process of manufacturing an electronic parts having a more complex circuit structure.

FIG. 3 shows an example of a manufacturing process for producing ceramic inductors using a sheet including an insulating layer 4 produced by the method according to the first embodiment. In this manufacturing process, firstly the recessed portion 4a and the through hole 4b of the insulating layer 4 formed on the base member 2 are filled with an electrode material 10 by, for example, screen printing (step 1). Next, the base member 2 is detached and removed from the insulating layer 4 having an internal electrode 10a and a penetrating electrode 10b obtained by filling with the electrode material 10 (step 2). Then, a predetermined number of (three, in the example shown in FIG. 3) ceramic green sheets 16 used for manufacturing inductors having an electrode produced in this way are stacked (step 3).

A pressure is applied to the stacked sheets in the thickness direction to bring the sheets in pressure contact with each other. With this press process, the principal portion of the ceramic inductor is formed. In this manufacturing process, the electrode material 10 fills the recess 4a and the through hole 4b in such a way that the surface of the electrode material 10 is substantially coplanar with the surface of the projected portion of the insulating layer 4. Hence, the thickness of the ceramic green sheet 14 used for manufacturing inductors is substantially uniform all over its area.

Therefore, it is possible to obtain a laminated member that can keep a shaped state well even with a small load pressure. Such a laminated member is cut into a specific size and subjected to sintering, so that a desired multilayer ceramic inductor is produced. With the use of the insulating layer 4 with reduced variations in surface evenness, shape and thickness produced by the method according to the present invention, it is possible to produce multilayer ceramic inductors in which variations in a certain electric characteristic are small as compared to conventional multilayer ceramic inductors.

The cross section of the pattern electrode or other parts produced by the method of the present invention has a preferable square shape, and therefore advantageous effects such as reduction of variations in the resistance of the inductor from a desired value or reduction of DC resistance are realized.

The sheet shown in step 1 of FIG. 3 may be produced by a method according to another embodiment of the present invention shown in FIG. 5. FIG. 5 shows a cross section of a sheet, as with the other drawings mentioned above, and parts similar to those in the structures shown in connection with the above-described embodiments will be designated by the same reference numerals. In the process of this embodiment, in step 1, a photosensitive layer 3 is formed on the top surface of the base member 2 and the light blocking layer 5 made of an electrode material formed at a predetermined position on the base member 2. The sheet as such is subjected to the process of steps 2 and 3 shown in FIG. 1 (which corresponds to the process of steps 2 and 3 in FIG. 5). Thus, a sheet having a light blocking layer 5 and a continuous recessed portion 4a is produced. In the mask 14 used in this embodiment, pattern 14a is designed to have a transmittance for ultraviolet light of about 100%, which means total transmission, while pattern 14b is designed to have a predetermined transmittance for ultraviolet light of about 50%. The recess 4a is filled with an electrode material 10 by means of a certain process so that an internal electrode 10a continuous with the light blocking layer 5 (penetrating electrode 10b) is formed. Then, the base member 2 is detached and removed from the sheet after the filling with the electrode material 10. Thus, a sheet used for forming inductors shown in step 5 is obtained. According to this method, since a penetrating electrode having a high aspect ratio for allowing connection between layers is formed in advance, it is considered that advantageous effects such as stability in the shape of the penetrating electrode or reliable connection of electrodes can be realized.

FIG. 4 shows a process of manufacturing multilayer electronic parts having a more complex circuit structure. The ceramic green sheet 18 shown in FIG. 4 is produced by filing the insulating layer 4 formed by the method according to the third embodiment with an electrode material by means of screen printing to form an internal electrode 10a and a penetrating electrode 10b separately. Ceramic green sheet 19 is composed of an insulating layer 4c and an electrode 10c. Ceramic green sheet 20 is composed of an insulating layer 4d and an electrode 10d. The penetrating electrode 10b is provided to connect the internal electrode 10c and the internal electrode 10d of the ceramic green sheets 19 and 20 disposed on the top and bottom of the ceramic green sheet 18. The internal electrode 10a is insulated from the internal electrode 10d of the lower sheet 20 and connected with the internal electrode 10c of the upper sheet 19. By using the sheet according to the present invention, electronic parts having the above-described structure can be manufactured easily.

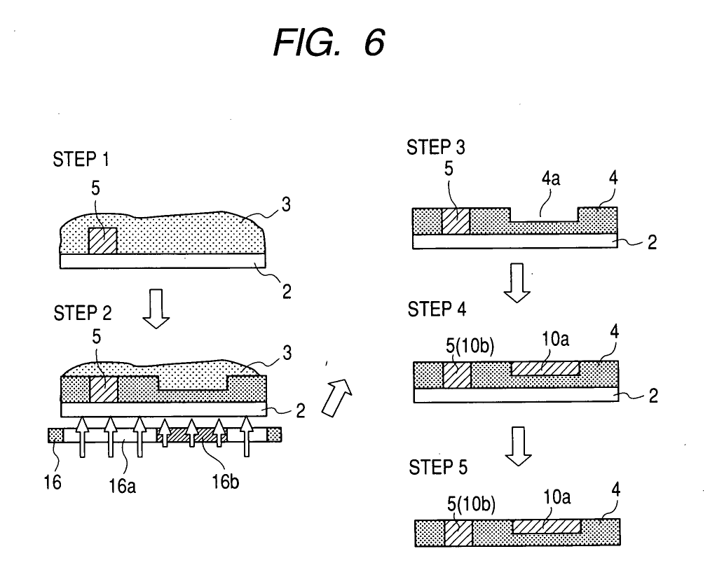

The sheet 18 shown in FIG. 4 may be produced by a method according to another embodiment of the present invention shown in FIG. 6. FIG. 6 shows a cross section of a sheet, as with the other drawings mentioned above, and parts in FIG. 6 similar to those in the structures shown in connection with the above-described embodiments will be designated by the same reference numerals. In the process of this embodiment, in step 1, a photosensitive layer 3 is formed on the top surface of the base member 2 and the light blocking layer 5 made of an electrode material formed at a predetermined position on the base member 2. The sheet as such is subjected to the process of steps 2 and 3 shown in FIG. 2 (which corresponds to steps 2 and 3 in FIG. 6). Thus, a sheet having a recessed portion 4a is produced. In the mask 16 used in this embodiment, pattern 16a is designed to have a transmittance for ultraviolet light of about 100%, which means total transmission, while pattern 16b is designed to have a predetermined transmittance for ultraviolet light of about 50%. The recessed portion 4a is filled with an electrode material 10 by a certain process so that an internal electrode 10a is formed. The base member 2 is detached and removed from the sheet after the filling with the electrode material 10. Thus, a sheet used for forming electronic parts shown in step 5 is obtained. According to this method, since a penetrating electrode having a high aspect ratio for allowing connection between layers is formed in advance, it is considered that advantageous effects such as stability in the shape of the penetrating electrode or reliable connection of electrodes can be realized.

This application claims priority from Japanese Patent Application No.2003-304218 filed Aug. 28, 2003, which is hereby incorporated by reference herein.

1. A method for manufacturing a ceramic green sheet utilizing an exposure process and a development process, comprising the steps of:
attaching a photosensitive material containing a powder having a specific electric characteristic to a front side surface of a member having a portion that can transmit light used in said exposure process, said photosensitive material being sensitive to said light, and said front side surface being a surface on which said ceramic green sheet is to be formed,
making light quantity of said light different for each of predetermined areas and then irradiating said photosensitive material with that light from the a back side of said member to perform said exposure process on said photosensitive material; and
performing said development process on said photosensitive material after said exposure process.

2. A method according to claim 1, wherein said light quantity of said light is made different for each of said predetermined areas by passing through a mask in which transmittances of its portions corresponding to said predetermined areas are different from each other.

3. A method according to claim 1, wherein said light quantity is differentiated into at least a light quantity obtained by fully blocking said light, a light quantity obtained by fully transmitting said lights and a light quantity obtained by partly transmitting said light by a predetermined ratio.

4. A method according to claim 3, wherein said exposure process is terminated when a thickness of a portion of said photosensitive material that is exposed to said light quantity obtained by partly transmitting said light by a predetermined ratio reaches a predetermined thickness.

5. A method according to any one of claims 1-4, further comprising a step of filling a recessed portion on said ceramic green sheet that is formed by said development process with an electrically conductive material.

6. A method according to any one of claims 1-4, further comprising a step of forming a light blocking portion composed of a material that does not transmit said light on a predetermined area of said front side surface of said member, prior to said step of attaching said photosensitive material to said front side surface of said member.

7. A method according to claim 1, wherein a releasing processing is applied to said member to facilitate release of said ceramic green sheet from said front side surface of said member.

8. A method for manufacturing a ceramic green sheet utilizing an exposure process and a development process, comprising the steps of:
attaching a photosensitive material containing a powder having a specific electric characteristic to a front side surface of a member having a portion that can transmit light used in said exposure process, said photosensitive material being sensitive to said light, and said front side surface being a surface on which a said ceramic green sheet is to be formed;
irradiating said photosensitive material with said light from a back side of said member to perform said exposure process on said photosensitive material, light quantity of said light being made different for each of predetermined areas; and
performing said development process on said photosensitive material after said exposure process.

9. A method according to claim 8, wherein said light comprises a light beam and light quantity is made different for each of said predetermined areas by scanning with said light beam.

10. A method according to claim 9, wherein scanning with said light beam is performed under a condition corresponding to each of said predetermined areas.

11. A method for manufacturing a multilayer electronic part comprising the steps of:
stacking a plurality of ceramic green sheets including a ceramic green sheet produced by a method for manufacturing a ceramic green sheet according to any one of claims 1-4 and 7-10; and
applying a pressure to said stacked ceramic green sheets in their thickness direction to form a laminated member.

12. A method for manufacturing a multilayer electronic part comprising the steps of:
stacking a plurality of ceramic green sheets including a ceramic green sheet produced by a method for manufacturing a ceramic green sheet according to claim 5; and
applying a pressure to said stacked ceramic green sheets in their thickness direction to form a laminated member.

13. A method for manufacturing a multilayer electronic part comprising the steps of:
stacking a plurality of ceramic green sheets including a ceramic green sheet produced by a method for manufacturing a ceramic green sheet according to claim 6; and
applying a pressure to said stacked ceramic green sheets in their thickness direction to form a laminated member.
